(19) United States
(12) Patent Application Publication
(10) Pub. No.: US 2020/0177220 A1
(43) Pub. Date: Jun. 4, 2020

(54) Digital stereo multiplexing-demultiplexing system based on linear processing of a Delta - Sigma modulated bit-stream

(71) Applicant: Djuro George Zrilic, Santa Fe, NM (US)

(72) Inventor: Djuro George Zrilic, Santa Fe, NM (US)

(21) Appl. No.: 16/350,540

(22) Filed: Nov. 30, 2018

(51) Int. Cl. H04B 1/16; H03M 7/32

(52) U.S. Cl. CPC H04B 1/1676; H03M 7/3017; H04B 1/1692

(57) ABSTRACT

Disclosed is a digital stereo multiplexing-demultiplexing system based on the use of delta-sigma modulation. Creation of left (L−R) and right (L+R) channels is achieved using a binary delta adder IC circuit. Delta adder is an ordinary binary adder with an interchanged role of the Sum and Carry-Out terminals. Two channel multiplexer and demultiplexer are implemented with ordinary binary logic gates. Output of the multiplexer is modulated and transmitted to the receiver where demultiplexing is performed. The proposed method can combine two or more digital stereo channels. This method is not application limited, and can be used in acoustic, video, or photo applications.

### CROSS REFERENCES TO RELATED APPLICATIONS

Fields, Craig D., U.S. Pat. No. 5,274,708, Date of patent: Dec. 28, 1993
Edgar, Albert D., U.S. Pat. No. 5,278,909, Date of patent: Jan. 11, 1994
Wildhagen, Jens, U.S. Pat. No. 7,092,460, Date of patent: Aug. 15, 2006
Newbery, Billy, U.S. Pat. No. 8,982,181, Date of patent: Mar. 17, 2015
Amadu, Frederic; Esnault, Thomas, U.S. Pat. No. 9,111,529, Date of patent: Aug. 18, 2015
Kamiya, Ryo, U.S. Pat. No. 6,438,434, Date of patent: Aug. 20, 2002
McArtur, Kelly; Hudson, Michael, US Patent No. 2007/0030986 A1, Date of patent: Feb. 8, 2007
Algazi, Ralph; Duda, Richard; Thompson, Dennis, US Patent No. 2008/0056517 A1, Date of patent: Mar. 6, 2008
Tatsuta, Akihiro; Nishikawa, Yoshikane; Funabiki, Makoto; Ohue, Hiroshi, US Patent No. 2009/0260043 A1, Date of patent: Oct. 15, 2009

### STATEMENT REGARDING FEDERALLY SPONSORED R&D

These research results are not sponsored by Government grants.

### NAME OF PARTIES TO A JOINT RESEARCH AGREEMENT

Individual project of Dr. Djuro G. Zrilic

### BACKGROUND OF INVENTION

### 1. Field of the Invention

The present invention relates to a method and apparatus for multiplexing-demultiplexing high-resolution digital stereo signals. A proposed digital stereo multiplexing system is based on:
a use of a high-resolution delta-sigma modulator (Δ-ΣM) as an analog-to-digital converter (ADC),
direct linear arithmetic operations on a Δ-Σ modulated bit-stream (addition/subtraction), and
a standard multiplexing digital technique.

Thus, the field of this invention is a non-conventional digital signal processing (DSP), based on addition/subtraction of a Δ-Σ modulated bit-stream.

### 2. Description of the Prior Art

A frequency modulation (FM) stereo broadcasting technique is well understood in literature and practice and it is regulated by federal law (FCC). This stereo broadcast is not limited to FM, the FCC has authorized some form of stereo AM broadcast as well. There are a number of books and references describing the FM stereo technique. In FIG. 1 a generic block diagram of a stereo FM system is shown [1]. Similar block diagrams of a stereo FM system can be found in many other references including the Internet. Thus, following general notation in this figure, we will briefly describe the operation of this system, and point out its implementation disadvantages. The idea of stereo is to provide a sound wave-front which replicates the depth and realism that individual experiences when listening. As can be seen in FIG. 1, the signal broadcast consists of two channels, left (L) and right (R). This signal can be derived from a microphone, tape or CD player, or other source. In the case of a broadcast of speech or music the frequency bandwidth is from 30 Hz to 15 kHz. With FM stereophonic broadcasting, voice or music channels are frequency division multiplexed onto a single FM carrier. The L and R audio channels are combined in analog adder networks to produce the L−R and L+R audio channels. As one can see, the L+R signal is used to modulate the carrier just as a non-stereo signal does. The L−R signal is shifted by a balance modulator (subcarrier frequency is 38 kHz) to produce a double sideband (DSB) suppressed carrier (SC) signal spanning 38-15=23 kHz, and 38+15=53 kHz. This process of stereo multiplexing is known as MPX. For demodulation purposes (synchronization), a 19 kHz pilot signal is also transmitted. All three signals are combined and delivered to a FM radio-frequency transmitter. Most FM transmitters now use an integrated circuit (IC). Motorola MC1376 IC is a complete FM modulator. Unfortunately, it requires several external analog components to make it operate (including two inductor (coil) components). Similarly, the XR-1310 stereo demodulator has a significant number of analog components. Thus, FM IC chips have to be buffered by a number of analog components which is not possible to integrate. There are several US patents proposing different digital stereo methods, but they are not related to the digital stereo multiplexing-demultiplexing method proposed in this invention. However, four of those patents are elaborated and compiled in this application:

1. Tatsuta et al discloses a wireless transmission system for wirelessly connecting signal source apparatus and signal sink apparatus (U.S. patent application Ser. No. 12/0888,832). From the proposed apparatus in FIG. 1, it is possible to see that a signal source is a DVD player, and a signal sink is a PDP apparatus. In FIG. 2 and in FIG. 3, a block diagrams are marked, but without any explanation how they operate, or how they are implemented. From the description and from the block diagrams it is not possible to resolve what kind of digital modulation technique is used for digital multiplexing: pulse code modulation (PCM), differential code modulation (DPCM), delta-sigma modulation (DSM) etc. Thus, from the description and from the block diagram, it is not possible to resolve how many bits per sample of video or audio signal is used (8-bit PCM, 16-bit PCM, etc.). From claims 19 to 34 it is possible to conclude that 2 channel wireless apparatus is proposed without mentioning delta-sigma modulation (DSM), arithmetic operations on delta-modulated bit-stream, or delta-sigma based stereo technique.

2. Kamiya disclosed mixing, coding and decoding devices and methods which the operation is based on mixed use of delta-sigma and pulse code modulation (U.S. patent application Ser. No. 08/864,552). From the proposed FIG. 1 one can see enormous complexity of the proposed digital signal processing circuitry. To avoid conversion of the data into analog domain, Kamiya proposes to mix 16-bit PCM signal and one-bit DSM bit-stream. However, this approach has some disadvantages. First, the decimation technique is silicon area consuming (complex) and expensive. Second, weighted 16-bit multipliers are bulky and slow (usually multiplication is done on the shift-and-add principle). Third, PCM adder (No. 13, in FIG. 1) is very complex. It adds four 16-bit PCM words and produces 17-bit word. Fourth, delta-sigma modulator (13), introduces additional quantization noise. It is important to mention that every one of those elements introduce additional noise into proposed system shown in FIG. 1. One can conclude, that the price and complexity of mixed “full-digital processing” (to avoid conversion of data into analog domain) is too big. Having a 16-bit word, one can expect the problem of reliability, because the most frequent malfunction happens at connection of metal wire and semiconductor (16 parallel wires/word)! Even though delta-sigma modulator is used as the ADC of the analog signal, entire DSP processing is done with 16-bit PCM code word, and at the output again converted into serial bit-stream using delta-sigma modulator.

3. Algazi et al proposed a new approach for tracking a head motion of headphone-based sound (U.S. patent application Ser. No. 11/845,607). In FIG. 1, of this invention, the basic concept of the invention is presented. It consists of microphone array, signal processing unit, and head tracker. From existing block diagrams and flow charts, it is impossible to conclude what kind of signal processor is employed. One cannot find data about the analog-to-digital convertor used and its resolution (a number of bits per sample), or any implementation solution. Without implementation schematics, measurement, or simulation results it is very difficult to judge the validity of the general concept proposed, or contrast and compare it with the existing solutions.

4. McArthur et al presented a wireless digital audio system which includes a transmitter that performs parallel acquisition of audio data from plural audio data. A set of Codecs convert the incoming multi-channel analog signal to serial digital bit stream. If a digital audio input signal is used, the Codecs can be bypassed. FIG. 3 of this invention (U.S. patent application Ser. No. 11/499,126) clearly presents radio transmitter including a timing marker for the packetization of parallel collected data. RF packet data stream is transmitted to the receiver (shown in FIG. 4 of this invention) which includes a timer unit responsive to receive a timing marker and a clock for synchronization and demultiplexing. In FIG. 5A and FIG. 5B one can see the complexity of the proposed wireless radio system. In addition to standard blocks, the transmitter consists of forward error correction block (FEC) and packet buffer block. The receiver has additional blocks for processing redundant and prior data. From block diagrams and from description it is not possible to conclude what kind of CODEC is used (PCM or Δ-Σ). In addition, direct processing of Δ-Σ bit stream is not mentioned at all.

It will be very difficult, if not impossible, to combine the techniques of Tatsuta, Kamaya, Algazi, McArthur, to obtain system proposed in this application. This application takes into account the main attributes of delta-sigma modulation analog-to-digital conversion technique: high resolution (more than 20 bits), simplicity of Δ-Σ M Codec, possibility of direct processing of Δ-Σ M bit-stream which enables the design of a simple Δ-Σ M arithmetic unit such as Δ-Σ adder/subtractor. Thus, the main difference between the prior art and the claims at issue is a novel delta-sigma stereo processing system, based on direct arithmetic operations on a delta-sigma bit-stream.

### BRIEF SUMMARY OF THE INVENTION

This invention introduces a novel delta-sigma based digital stereo multiplexing-demultiplexing system. Operation of a multiplexer-demultiplexer is based on the use of a high resolution Δ-Σ modulator, four binary delta adders (ΔA) [2], and two-channel digital multiplexers-demultiplexers.

The operation of the proposed digital stereo multiplexer-demultiplexer will be apparent upon consideration of the following detailed description taken in conjunction with the accompanying drawings. The present invention includes:
1. A method and apparatus for digital stereo multiplexing, based on arithmetic operation of addition and subtraction of a Δ-Σ modulated bit-stream.
2. A method and apparatus for digital stereo demultiplexing of a multiplexed Δ-Σ modulated bit-stream.

It is, therefore, a primary objective of the present invention to provide a method for multiplexing of two (or more) Δ-Σ modulated stereo bit-streams, produced by addition and subtraction of a two one-bit streams.

It is still the objective of the present invention to provide a method for demultiplexing two digital stereo signals, produced by addition and subtraction of a one-bit demultiplexed bit stream.

It is an additional objective of this invention to perform addition/subtraction on a second-order (or higher-order) Δ-Σ modulated bit-stream.

Yet another objective of the present invention is to provide a method for digital stereo multiplexing-demultiplexing of audio, photo, and video signals.

Finally, it is the objective of the present invention to provide a digital stereo multiplexing-demultiplexing system for long or short-distance transmission in industrial (not licensed) or licensed frequency bandwidth (BW).

### BRIEF DESCRIPTION OF DRAWINGS

FIG. 1 shows a block diagram of the FM stereo system (Prior Art).

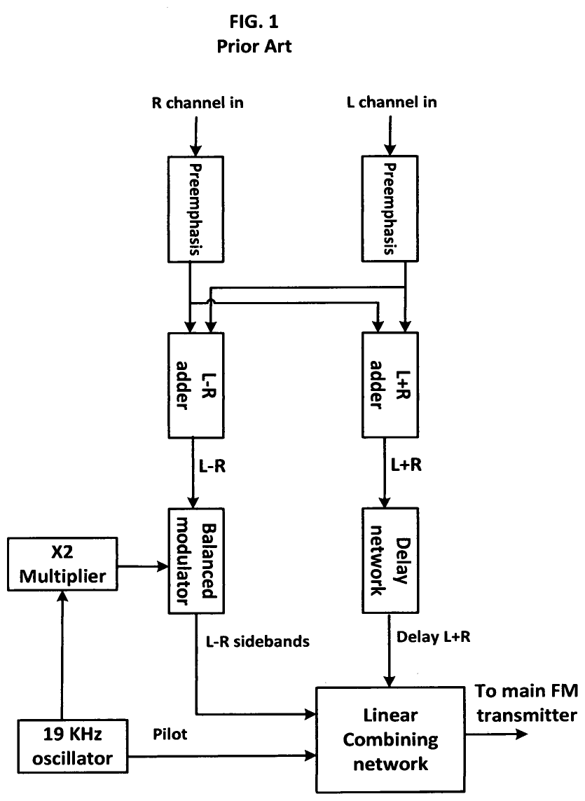

FIG. 2 shows a block diagram of a binary delta adder (Prior Art).

FIG. 3 shows the proposed digital stereo multiplexing-demultiplexing system.

FIG. 4 shows input-output waveforms for identical input signals MK1 and MK2.

FIG. 5 shows input-output waveforms for two different signals of MK1 and MK2.

FIG. 6 shows a block diagram of the proposed integrated circuit (IC) chip.

### DETAILED DESCRIPTION OF THE INVENTION

### Definition

A stereo multiplexing-demultiplexing system is the main component of any stereo transmission system. Most existing stereo techniques are based on a frequency multiplexing technique. The proposed method of this invention consists of a high resolution Δ-Σ modulator whose resolution is greater than 20 bits. In addition to the simple and inexpensive high-resolution Δ-Σ modulator implementation [3], [4], it is possible to perform linear arithmetic operations of addition, subtraction, and multiplication by a constant less than 1 on its bit-stream. To implement addition/subtraction of the left (L) and right (R) channels a special circuit must be developed. An ordinary serial binary adder, with interchanged role of the terminals of Carry-Out and Sum, can perform addition/subtraction of two Δ-Σ modulated bit-streams [2]. Thus, the main contribution of this invention is a simple, inexpensive and reliable digital stereo multiplexing-demultiplexing system, based on a direct arithmetic operation on a Δ-Σ modulated bit-stream.

### The Best Mode of Invention

The block diagram of the proposed method, with supporting simulation results, is presented. Herein the best mode contemplated by the inventor shell be presented.

### How to Make the Invention

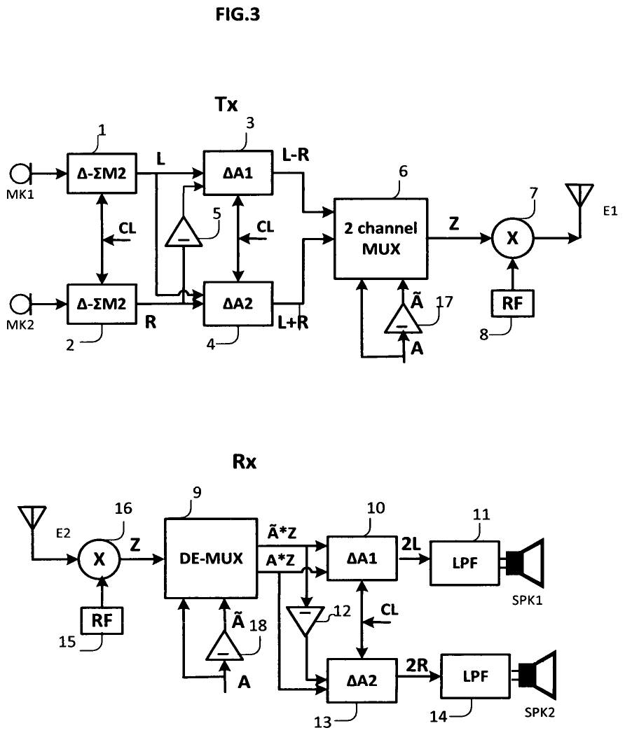

As can be seen from FIG. 3 the proposed system consists of a number of distinct components. Thus, it is necessary to describe every component separately.

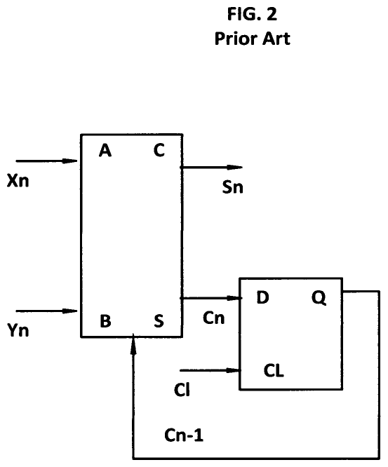

FIG. 3 shows a block a diagram of a proposed stereo transmitter (Tx) and receiver (Rx). Even though any type of higher order Δ-Σ modulator can be employed as ADC in our simulation model, a second-order Δ-Σ modulator is used. Without loss of generality, instead of a microphone (MK1 and MK2), different transducers can be used such as a photo camera, recorded CD or taped music. For example, a transducer can be integrated with a Δ-Σ modulator to implement a digital mike or stereo sensing system for robotic applications. Δ-Σ modulators (1 and 2) are highly oversampled where sampling frequency is much higher than a frequency of an input signal (F_{sampling}>>2F_{B}, where 2F_{B} is Nyquist sampling frequency). Depending on the application the oversampling factor R can vary (R=F_{samp.}/2F_{B}). Δ-Σ modulated bit-streams, L and R, are added in a delta adder ΔA2 (4) to produce a binary bit-stream L+R. To produce a bit-stream L−R, the R bit-stream must be first inverted (5) and added to a bit stream L in ΔA1 (3). The block diagram of a binary ΔA is shown in FIG. 2 (Prior Art) as an ordinary serial binary adder with interchanged roles of Sum and Carry-Out terminals. According to Kouvaras [2] the Sum of two delta modulated bit-streams is defined as

Sn=½[Ln+Rn]+error (1)

The error signal consists of both quantization noise and Carry-Out propagation noise. This error can be minimized with proper design (higher order modulator) and increase of a sampling frequency. One can see that a ΔA introduces an attenuation of one half. Depending on a sign of Carry-Out of delta adder, Ln and Rn have always the same sign. Thus, Sn is always +1 or −1 [2]. If needed, one can overcome this attenuation by amplification at a receiver. Δ-Σ modulated bit-streams L−R and L+R are multiplexed using 2 channel multiplexers (6) with binary address A. The output Z of multiplexer is given by Boolean expression

Z=Ã*(L−R)+A*(L+R)

If A=“1” L+R bit-stream is passed to the RF modulator (7), and if A=“0” (Ã=“1”) then the L−R bit-stream is modulated in (7). Depending on the application, a digital bit-stream can be modulated using different types of modulation such as FM, AM, ASK, etc. Radio signals can occupy different frequency bandwidths, licensed or unlicensed. Thus, a proposed stereo digital apparatus is not application limited.

Stereo receiving system Rx, shown in FIG. 3, consists of a standard RF receiver (15) and (16) to produce a signal Z. Digital bit-stream Z is fed into a demultiplexer whose outputs are given by Boolean expression

Ã*Z=Ã*[Ã*(L−R)+A*(L+R)]=Ã*(L−R), and

A*Z=A*[Ã*(L−R)+A*(L+R)]=A*(L+R)

One can see if A=“1” then L+R is passed to both ΔA1 (10) and ΔA2 (13). Inverting Ã*Z in (12) one gets −L+R. Thus, output of ΔA2 (13) is L+R−L+R=2R. Similarly, output of A1 is 2L when A=0. It is important to remember that a delta adder performs algebraic operations (not Boolean) on a delta-sigma bit stream. Inversion means change of sign of binary signal (+1 to −1 or −1 to +1).

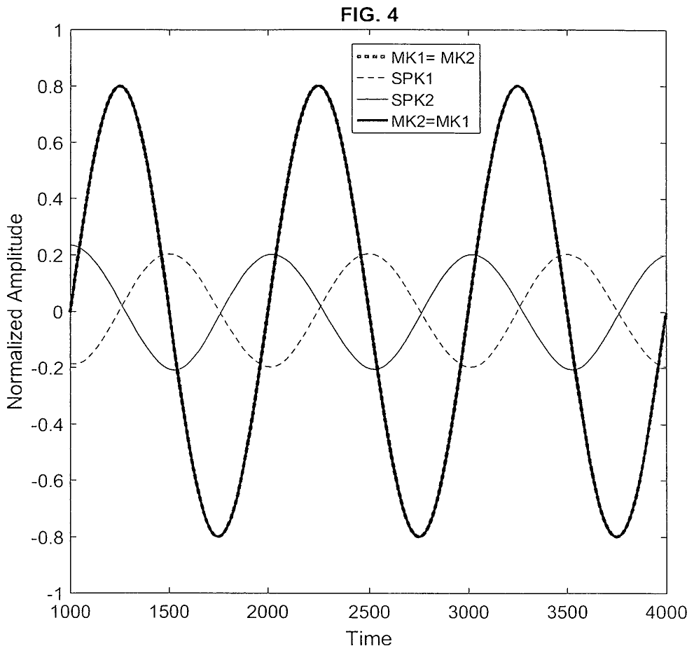

In FIG. 4 simulation results are shown when both sound signals are identical (frequency and amplitude of mikes signals, MK1 and MK2, are identical). It is shown that received signals, SPK1 and SPK2, are identical (they are inverted for clarity reasons). According to equation (1) ΔA introduces attenuation of ½ at the transmitting site. Similarly, ΔA introduces attenuation of ½ at the receiver. Thus, the total channel attenuation is ¼. During the demultiplexing process delta adder adds two identical signals, thus overall channel attenuation is ½. However, demodulating LPF (11) and (14) introduce additional attenuation which depends on the order of a filter and its cut-off frequency.

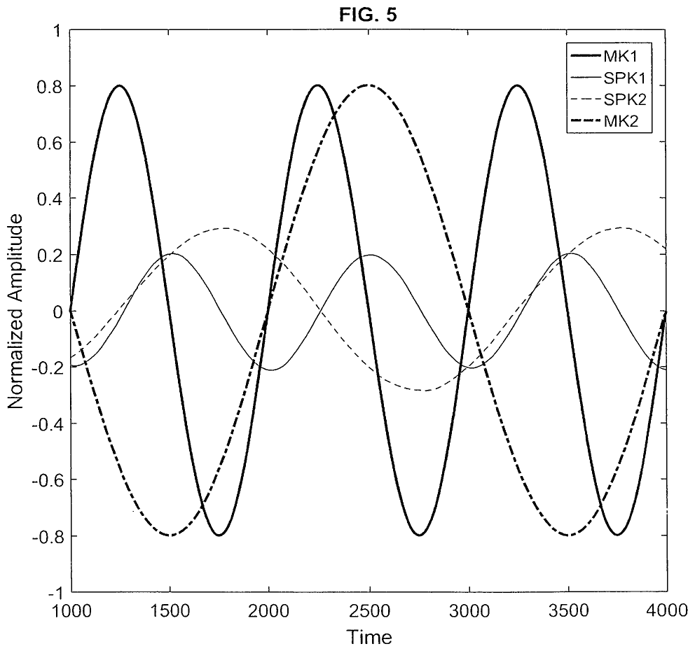

FIG. 5 shows an example of two input signals (MK1, MK2) of two different frequencies (F_{MK1}=2F_{MK2}). Again, one can see correctly demodulated waveforms SPK1 and SPK2. If needed received signals SPK1 and SPK2 can be amplified.

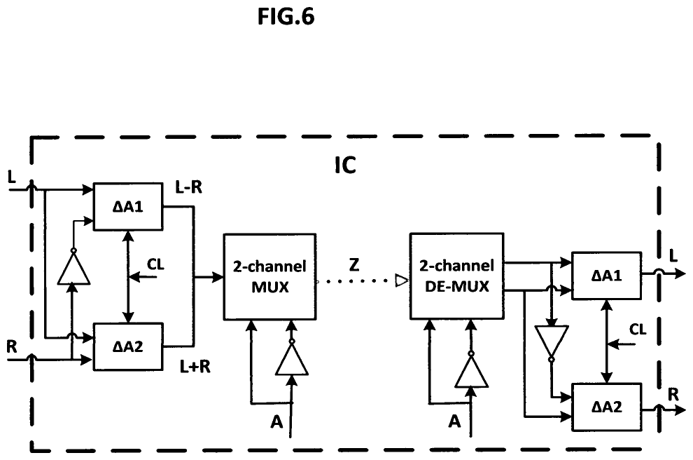

FIG. 6 shows an IC chip, which consists of the following digital circuits: 4 delta adders, 4 inverters, 2-channel multiplexer and 2-channel demultiplexer. Depending on the application, one can envision different scenarios of integration. One possibility is shown if FIG. 6. The proposed IC system can be integrated with a delta-sigma modulator and transducer as well to implement a system on chip (SoC). Another option is in multiplexing 4 or more channels. Yet another possibility is to multiplex output Z with identical output of a second IC chip. Even though digital multiplexing technique is well established in many areas of engineering and science, there is still space for originality. It is obvious that a possibility of direct processing of a delta-modulated bit-stream leads to a novel solution of a system-on-chip (SoC) shown in FIG. 6. It is also obvious that a delta-sigma multiplexed bit-stream (signal Z), can be modulated in many different ways (put on RF carrier), and transmitted wirelessly, or over other transmission media. It is not obvious that prior art solutions could lead to the claims at issue in this application.

### How to Use the Invention

Stereo is a method of sound reproduction that creates an illusion of multidirectional audible perception. Using two or more independent channels connected with two or more loudspeakers can create the impression of sound coming from various directions as in natural hearing. Stereo sound is common in entertainment systems such as broadcast radio, TV, cinema or recorded music. In addition, stereo photography is a method to produce stereoscopic images, videos, or films. This is usually achieved using specially built stereo cameras, paired or single. In stereo photography the goal is to duplicate natural human vision. Stereo techniques could be used to help pilots fly planes, to help a ground-based crew to fly drones, and to navigate unmanned vehicles or robots. Regardless of what kind of stereo application one choses, the correct baseline (distance between left and right mike, or camera, or where two images are taken) is of critical importance. However, selection of the correct baseline does not help if a high-resolution digital transducer (mike or camera) does not exist. The proposed method of digital stereo multiplexing uses a high-resolution delta-sigma modulator (resolution greater than 20 bits) as the analog-to-digital converter. Its use can be found in acoustic and video applications. A novel method of stereo multiplexing and creation of left and right digital channels is based on non-conventional digital signal processing using a delta adder. It is apparent to one familiar with the art of non-conventional signal processing that a digital stereo signal Z can be combined (multiplexed) serving different purposes.

What is claimed is:

1. A digital stereo multiplexing apparatus comprising:
a two transducer;
a two second-order or higher-order delta-sigma modulator;
an inverter;
a two-delta adder;
a binary address A;
a two-channel multiplexer; and
a radio-frequency transmitter.

2. A digital stereo demultiplexing apparatus comprising:
a radio-frequency receiver;
a two-channel demultiplexer;
a binary address A;
an inverter;
a two-delta adder;
a two low-pass filter; and
a two transducer.

3. A delta-sigma modulation digital processing system on chip (SoC) comprising:
a left (L) and right (R) delta-sigma modulated channels;
a two-delta adder with an inverter;
a two-channel multiplexer with an output Z, an inverter, and a binary address A;
a two-channel demultiplexer with an inverter and a binary address A; and
a two-delta adder with an inverter and an output delta-modulated bit-streams L and R.
